(19) United States
(12) Patent Application Publication
(10) Pub. No.: US 2026/0367109 A1
(43) Pub. Date: Nov. 19, 2026

(54) TESTING DEVICE AND METHOD FOR TESTING AN ELECTRONIC DEVICE

(71) Applicant: JCET STATS ChipPAC Korea Limited, Incheon (KR)

(72) Inventors: MyungKi KIM, Incheon (KR); JiHyoung YU, Seoul (KR)

(21) Appl. No.: 19/672,572

(22) Filed: May 9, 2026

(30) Foreign Application Priority Data
May 13, 2025 (CN) 202510612388.9

(51) Int. Cl. G01R 1/04; G01R 1/073

(52) U.S. Cl. CPC G01R 1/0466; G01R 1/07307

(57) ABSTRACT

A testing device and a method for testing an electronic device are provided. The electronic device comprises a socket board, a plurality of contact pads on the socket board, and a socket unit mounted on the socket board. The testing device is operably connected to the electronic device. The testing device comprises a probe assembly and a housing. The probe assembly is configured to operably contact a plurality of contact pins to electrically lead out the plurality of contact pins from the electronic device. The probe assembly comprises a probe guiding block, a substrate and a probe. The housing is coupled to the probe assembly to operably fix the probe assembly to the socket body of the electronic device to allow the probe to be electrically coupled to the socket board of the electronic device through the substrate.

### TECHNICAL FIELD

The present application generally relates to measurement technology, and more particularly, to a testing device and a method for testing an electronic device.

### BACKGROUND OF THE INVENTION

The semiconductor industry is constantly faced with complex integration challenges as consumers want their electronics to be smaller, faster and higher performance with more and more functionalities packed into a single device. Electronic components that have undergone complicated processing are subject to various types of electrical tests for testing their characteristics and for identifying their potential defects.

To this end, a testing socket is used to electrically connect metallic wires or contact pads of a socket board (for example, a printed circuit board) mounted in testing equipment with connectors or terminals of an electronic component to be tested. That is, when an electronic component is being tested, the testing socket serves as an interface to electrically connect the socket board of the testing equipment with the electronic component under test. Establishing the connection between the testing equipment and the electronic component under test may induce a path loss that results in deterioration of the device performance, especially when the electronic component is tested by high frequency signals. Thus, the path loss should be calibrated from test results of the electronic component to remove the deterioration of the device performance that occurs during the testing process, and improve accuracy of the test results. However, it is difficult to measure the path loss induced by the test socket and the socket board conveniently by using the existing testing device.

Therefore, a need exists for a testing device and a method for testing an electronic device.

### SUMMARY OF THE INVENTION

An objective of the present application is to provide a testing device and a method for testing an electronic device.

According to an aspect of the present application, a testing device for testing an electronic device. The electronic device comprises a socket board, a plurality of contact pads on the socket board, and a socket unit mounted on the socket board; wherein the socket unit comprises a socket body, a testing cavity formed the socket body and a plurality of contact pins vertically extending through the socket body and exposed from the testing cavity, each contact pin being aligned with and operably connected to one of the plurality of contact pads. The testing device is operably connected to the electronic device and comprises: a probe assembly and a housing. The probe assembly is configured to operably contact the plurality of contact pins to electrically lead out the plurality of contact pins from the electronic device, and comprising: a probe guiding block matable with the testing cavity to be operably accommodated in the testing cavity, wherein the probe guiding block comprises a probe passage vertically extending through the probe guiding block; a substrate disposed at a bottom of the probe guiding block, wherein the substrate comprises a plurality of conductive contact pads formed at a first side of the substrate and a probe connector mounted at a second side of the substrate, the first side being opposite to the second side, the probe connector being electrically coupled to the plurality of conductive contact pads, wherein the substrate is configured that each conductive contact pad of the plurality of conductive contact pads is aligned with and connected to one of the plurality of contact pins when the probe guiding block is accommodated in the testing cavity; and a probe extending through and accommodated in the probe passage, wherein the probe comprises a first end connected to the probe connector and a second end facing away from the probe connector. The housing is coupled to the probe assembly, and configured to operably fix the probe assembly to the socket body of the electronic device to allow the probe to be electrically coupled to the socket board of the electronic device through the substrate.

According to another aspect of the present application, a testing method is provided. The electronic device comprises a socket board, a plurality of contact pads on the socket board, and a socket unit mounted on the socket board; wherein the socket unit comprises a socket body, a testing cavity in the socket body and a plurality of contact pins vertically extending through the socket body and exposed from the testing cavity, each contact pin being aligned with and operably connected to one of the plurality of contact pads; and wherein the method comprises providing a testing device, wherein the testing device comprises: a probe assembly configured to operably contact the plurality of contact pins to electrically lead out the plurality of contact pins from the electronic device, and comprising: a probe guiding block matable with the testing cavity to be operably accommodated in the testing cavity, wherein the probe guiding block comprises a probe passage vertically extending through the probe guiding block; a substrate disposed at a bottom of the probe guiding block, wherein the substrate comprises a plurality of conductive contact pads formed at a first side of the substrate and a probe connector mounted at a second side of the substrate, the first side being opposite to the second side, the probe connector being electrically coupled to the plurality of conductive contact pads; and a probe extending through and accommodated in the probe passage, wherein the probe comprises a first end connected to the probe connector and a second end facing away from the probe connector; and a housing coupled to the probe assembly; connecting the housing of the testing device to the socket body of the socket unit, such that the probe guiding block is accommodated in the testing cavity and each conductive contact pad of the plurality of conductive contact pads is aligned with and connected to one of the plurality of contact pins; and connecting a first signal cable coupled to the probe and a second signal cable coupled to the reference connector of the socket board to a signal measurement instrument, to enable testing of the electronic device by the signal measurement instrument through the testing device.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1A is a cross-sectional view when a testing device for testing an electronic device is operably connected to the electronic device according to an embodiment of the present application.

FIG. 1B is a perspective view of an electronic device and a testing device for testing the electronic device according to an embodiment of the present application.

FIG. 1C is a structural diagram of a probe assembly according to an embodiment of the present application.

FIG. 1D is a structural diagram of a substrate according to an embodiment of the present application.

FIG. 1E is a layout of a plurality of conductive contact pads of a substrate according to an embodiment of the present application.

FIG. 1F is a cutaway view of a testing device according to an embodiment of the present application.

FIG. 2 illustrates a method for testing an electronic device according to an embodiment of the present application.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As mentioned above, when an electronic component is being tested by a testing device including a testing socket and a socket board, a path loss may be inevitably induced into test results generated by the testing apparatus. To be more specific, the testing socket may include pogo pins or similar connection components which help establish electrical connections between the electronic component and the socket board to test the electronic component. During this testing process, the path losses induced by the pogo pins and other connection components in signaling paths may inevitably occur and be incorporated within a test result of the electronic component. Therefore, it is desired to remove the path loss from the test result, so as to improve accuracy of the test result of the electronic component. However, it is difficult to accurately and conveniently measure path losses using conventional test devices.

Some solutions have been provided to measure path losses of pogo pins. For example, a simulation of the path loss, or a pre-measured result of the path loss provided by pogo pin vendors may be used for calibration of a test result of an electronic component under test, instead of an actual measurement of the path loss when the electronic component is being tested. However, since this calibration information which is generated or measured beforehand is obtained in environments different from an actual testing environment of the electronic component, the accuracy of the calibration information of the path loss may still be unsatisfactory. In addition, when the path loss is measured beforehand, probes are generally used for connecting the pogo pins to measure the path losses. However, this measuring process may suffer from several issues such as poor contact reliability and deficient probe durability.

To address the above issues, a testing device and a method for testing an electronic device such as a socket are provided by the present application. The electronic device is used for testing electronic components such as semiconductor chips, semiconductor packages, or similar components. The electronic device includes a socket unit for accommodating the electronic component(s). The testing device and method provided by the present application can be used to test and calibrate this kind of electronic devices, avoiding or eliminating errors in the testing of electronic components. The testing device can fix a probe assembly to a socket body of the electronic device to allow a probe in the probe assembly to be electrically coupled to the socket board of the electronic device, thereby testing the path loss or other electrical characteristics introduced by the socket unit.

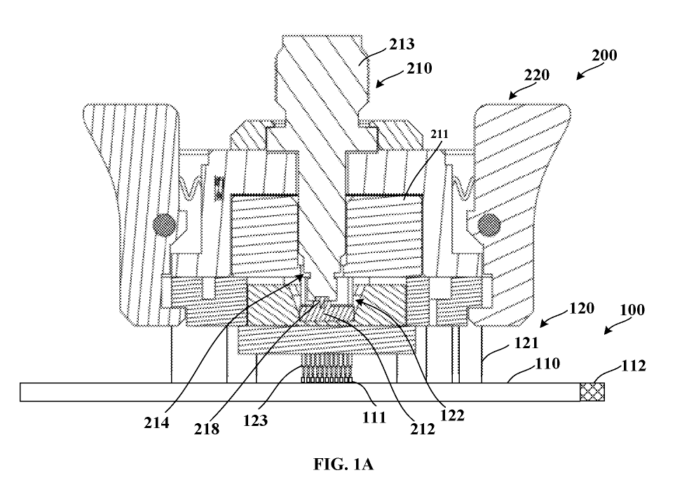

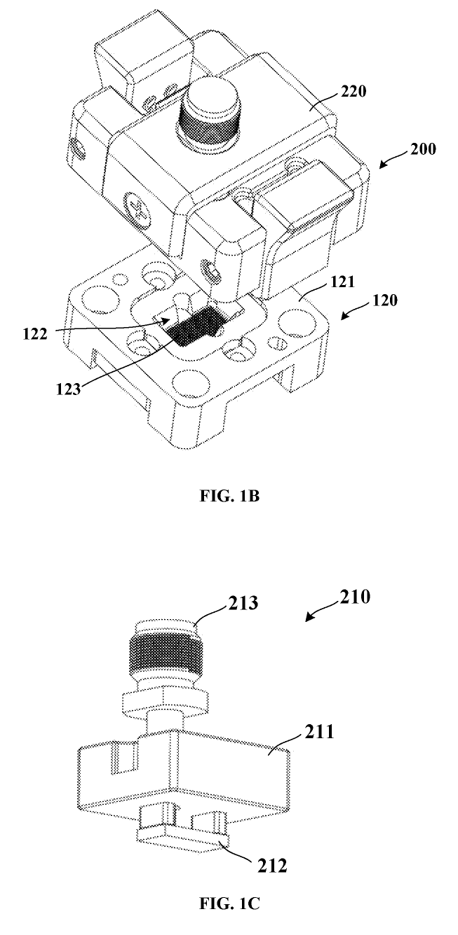

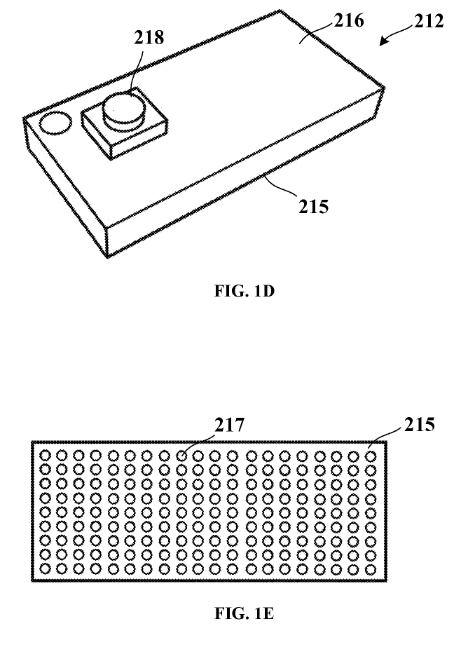

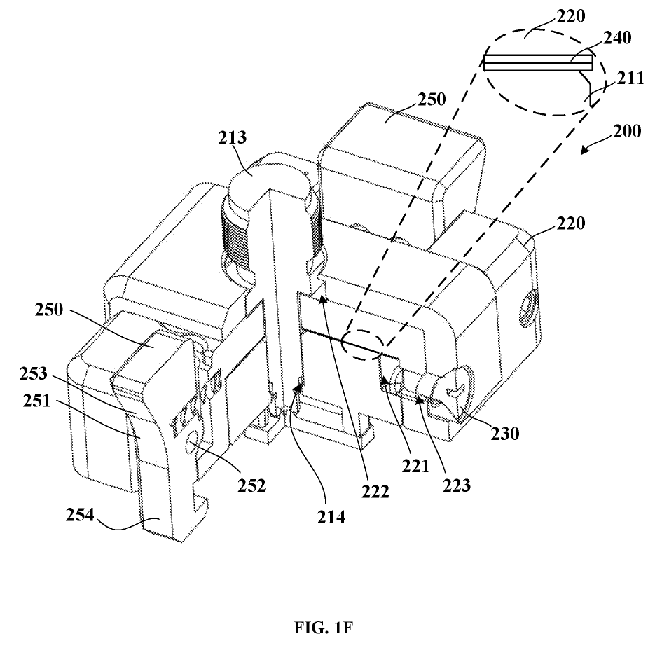

FIG. 1A is a cross-sectional view when a testing device 200 for testing an electronic device 100 is operably connected to the electronic device 100 according to an embodiment of the present application. The electronic device 100 can be a device used for testing electronic components, for example, the electronic device 100 can be a socket. The testing device 200 being operably connected to the electronic device 100 refers to that the electronic device 100 and the testing device 200 are connected in a way that enables signal transmission, control, or function implementation when the testing device 200 is mounted on the electronic device 100. However, the electronic device 100 can be separated from the testing device 200 and not connected with the testing device 200 when the testing device 200 is not mounted on the electronic device 100, i.e., when removed, such that the electronic device 100 can be used to connect and test the electronic components. As shown in FIG. 1A, the electronic device 100 includes a socket board 110 and a socket unit 120 mounted on the socket board 110. The socket board 110 includes a plurality of contact pads 111, a reference connector 112, and a first signaling trace (not shown).

In some embodiments, the socket board 110 can serve as the base of the electronic device 100. The testing device 200 can be electrically connected to the socket board 110 via a plurality of contact pins 123 of the socket unit 120 when the testing device 200 is testing the electronic device 100. Thus, the testing device 200 can receive power, control signals or drive signals from the socket board 110, or send test results or data back to the socket board 110. Additionally, the socket board 110 can also be connected to external testing equipment, such as a multimeter, which may or may not include a signal generator for testing electronic components.

In some embodiments, the reference connector 112 can be a connector used for radio-frequency (RF) applications, primarily for detection, transmission, and connection of high-frequency electronic signals. The reference connector 112 consists of an interface section and a probe section. The interface section features a standard threaded structure to ensure stable and reliable connections, particularly in high-frequency signals to maintain good electrical performance. The probe section is used to directly contact an object under test and is usually made of a metal material with good conductivity and elasticity to ensure a reliable connection with the object under test. Furthermore, the probe can have a shape which may vary, for example, the probe can be straight, bent, or claw-shaped, to suit different testing environments and different shapes of the object under test.

In some embodiments, the first signaling trace may be distributed within the socket board 110, for example, to connect a contact pad 111 to a measurement module mounted on or otherwise connected to the socket board 110, or to the reference connectors 112. The first signaling trace extends between the contact pad 111 and the reference connector 112 which are electrically coupled with each other, thus enabling signal transmission between the contact pad 111 and the reference connector 112. In some embodiments, the signaling trace can be a high-frequency (RF) trace. The signaling trace is designed to transmit RF signals, typically used to guide signals to a desired location or to measure impedance.

FIG. 1B is a perspective view of an electronic device and a testing device for testing the electronic device according to an embodiment of the present application. Referring to FIGS. 1A and 1B, the socket unit 120 includes a socket body 121, a testing cavity 122 formed in the socket body 121, and a plurality of contact pins 123 vertically extending through the socket body 121 and exposed from the testing cavity 122, each contact pin being aligned with and operably connected to one of the plurality of contact pads 111.

In some embodiments, the testing cavity 122 is enclosed by a sidewall of the socket body 121 and is used to accommodate an electronic component when the electronic component is being tested, or to accommodate the testing device 200 when the electronic device 100 is being tested and calibrated. Additionally, the testing cavity 122 can include at its top a device loading opening connected to the inside of the testing cavity 122 to allow the electronic component or the testing device 200 to be received in the testing cavity 122 through the device loading opening. The testing cavity 122 can also include a guide member disposed at the device loading opening, which is used to guide the electronic component or the testing device 200 to move to a predetermined testing position within the testing cavity 122. The guide member can include one or more inclined surfaces.

It is understood that, during the actual testing, operational errors may occur when the electronic components or the testing device 200 is placed into the testing cavity 122, resulting in improper positioning of the electronic components or the testing device 200 which may affect the test results. However, by forming the guide member within the testing cavity 122, even if there is a certain degree of deviation in alignment of position when the electronic components or the testing device 200 is placed into the testing cavity 122, the guide member can guide the electronic components or the testing device 200 to move to the predetermined test position The accuracy of the testing is thus ensured.

In some embodiments, the contact pin 123 being operably connected to the contact pads 111 refers to that the contact pins 123 and the contact pads 111 are connected in a way that enables signal transmission, control, or function implementation when the electronic component or the testing device 200 is mounted on the socket unit 120 because a certain pressing force can be applied to the contact pins 123 to move them downward towards the contact pads 111. However, the contact pins 123 can be separated from the contact pads 111 and not connected to the contact pads 111 when the electronic component or the testing device 200 are not mounted with the electronic device 100, i.e., removed.

In some embodiments, the contact pins 123 can have the same structure. For example, the contact pins 123 can include pogo pins. Each pogo pin includes a pipe-shaped pin body, a metallic top contactor coupled to a top end of the pin body, a metallic bottom contactor coupled to a bottom end of the pin body, and a compressible coil spring disposed inside the pin body. The compressible coil spring can be in contact with a top contactor at its top end, and can be in contact with a bottom contactor at its bottom end. As such, the pogo pins 123 can be movable vertically relative to the socket body 121 with the coil spring providing an elastic connection between the electronic components or the testing device 200 and the socket board 110. With these configurations, the top contactors of the pogo pins 123 can be in contact with the conductive pads of the electronic components or the testing device 200, and the bottom contactors of the pogo pins 123 can be in contact with the contact pads 111 on the socket board when the top contactors of the pogo pins 123 are pressed by the electronic components or the testing device 200. Additionally, the top contactors and the bottom contactors are exposed from the front surface and the back surface of the socket body 121. In this way, the contact pins 123 may be pressed against the socket board 110 to set up a reliable electrical connection between the electronic components or the testing device 200 and the socket board 110, thereby creating a testing environment or system to test the electronic components or to be tested by testing device 200 (during calibration). In some other embodiments, the contact pins 123 can include other types of elastic connectors, such as elastic conductive posts.

As shown in FIGS. 1A and 1B, the testing device 200 includes a probe assembly 210 for connecting with the contact pins 123 of the electronic device 100. FIG. 1C is a structural diagram of the probe assembly 210 according to an embodiment of the present application. As shown in FIGS. 1A and 1C, the probe assembly 210 includes a probe guiding block 211, a substrate 212 disposed at a bottom of the probe guiding block 211, and a probe 213. FIG. 1D is a structural diagram of the substrate 212 according to an embodiment of the present application. As shown in FIG. 1D, the substrate 212 includes a first side 215 and a second side 216 which are opposite to each other. A probe connector 218 is mounted at the second side 216 of the substrate 212, and the probe connector 218 can be a connector used for RF applications. For example, the connector with Model No. MM8830 which is commercially available from Murata Manufacturing Co., Ltd. can be used as the probe connector 218. In some embodiments, the probe connector 218 can be mounted at the second side 216 of the substrate 212 using surface mount technology. FIG. 1E is a layout of a plurality of conductive contact pads 217 in the substrate 212 according to an embodiment of the present application. As shown in FIG. 1E, the plurality of conductive contact pads 217 are formed at the first side 215 of the substrate 212, and the plurality of conductive contact pads 217 can be gold fingers or other components with the function of transmitting current or signals. The layout of the plurality of conductive contact pads 217 is mating with the layout of the plurality of contact pins 123. The plurality of conductive contact pads 217 are operably connected to the plurality of contact pins 123 when the probe assembly 210 is mounted on the socket body 121 of the electronic device 100. That is, the plurality of conductive contact pads 217 and the plurality of contact pins 123 are connected in a way that enables signal transmission and control, so as to electrically lead out the plurality of contact pins 123 from the electronic device 100. In addition, the probe connector 218 is electrically coupled to the plurality of conductive contact pads 217. Specifically, there can be a second signaling trace (not shown) between each conductive contact pad of the plurality of conductive contact pads 217 on the substrate 212 and the probe connector 218 to electrically couple the probe connector 218 and the plurality of conductive contact pads 217 and transmit signals between them. Similar to the first signaling trace, the second signaling trace can also be a high-frequency (RF) trace. For example, the second signaling trace may include a through via vertically extending through the substrate 212 and connected to the conductive contact pad 217, and a conductive wire connected between the through via and the probe connector 218 and extending along the substrate 212. In some embodiments, each conducive contact pad 217 may be coupled to the probe connector 218 by a pair of through via and conductive wire, and a switch may be coupled between the second signaling traces for the plurality of conductive contact pads 217. And if any of the conductive contact pads 217 needs to be tested, the switch may enable the second signaling trace for the specific conductive contact pad 217 and disable the other second signaling traces. As shown in FIGS. 1A-1C, the shape of the probe guiding block 211 is designed to be mating with the testing cavity 122, so that the probe guiding block 211 is well accommodated in the testing cavity 122 when the probe assembly 210 is fixed to the socket body 121 of the electronic device 100. In addition, the probe guiding block 211 includes a probe passage 214 vertically extending through the probe guiding block 211. The probe 213 can extend through and be accommodated in the probe passage 214, so that the first end of the probe 213 is connected to the probe connector 218, and the second end of the probe 213 is facing away from the probe connector 218. In some embodiments, the probe 213 can be a probe, with its first end being a probe part and its second end being an interface part. For example, a connector with Model No. MM126711 which is commercially available from Murata Manufacturing Co., Ltd. can be used as the probe 213. When the probe 213 extends through and is accommodated in the probe passage 214, the probe part is connected to the probe connector 218.

As shown in FIGS. 1A and 1B, the testing device 200 further includes a housing 220. The housing 220 is coupled to the probe assembly 210 for protecting the probe assembly 210 and assisting the probe assembly 210 to be fixed to the electronic device 100. For example, the housing 220 can cover the outside of the probe assembly 210 and be coupled to the probe assembly 210 by adhesive or other fixing methods. The probe assembly 210 can be operably fixed to the socket body 121 of the electronic device 100 through the housing 220. As such, the probe guiding block 211 is accommodated in the testing cavity 122, and the probe 213 is electrically connected to the socket board 110 of the electronic device 100 through the substrate 212.

As shown in FIG. 1A, when the testing device 200 is operably connected to the electronic device 100, the probe guiding block 211 is operably accommodated in the testing cavity 122, and each of the plurality of conductive contact pads 217 is aligned with and connected to one of the plurality of contact pins 123. A test path is thus formed from the reference connector 112 to the probe 213. In this embodiment, it is exemplarily described that the testing device 200 is only testing one of the plurality of contact pins 123 or its related path loss. In this case, the contact pin to be tested is referred to as a target contact pin, the contact pad electrically connected to the target contact pin is referred to as a target contact pad, and the conductive contact pad to be tested is referred to as the target conductive contact pad. The test path starts from the probe 213, extends to the probe connector 218, then to the target conductive contact pad, then to the target contact pin, then to the target contact pad, and finally reaches the reference connector 112. In a specific implementation, a control component can be provided on the socket board 110 to selectively enable the signaling line from the reference connector 112 to the target contact pad, and disconnect the signaling line from the reference connector 112 to other non-target contact pads other than the target contact pad. A test result can be generated by measuring the electrical characteristic associated with the test path.

In some embodiments, the testing device 200 can further include a testing module which is not shown. The testing module generates the test result by measuring the electrical characteristic associated with the test path when the testing device 200 is connected to the socket unit 120. The testing module can be electrically coupled to the second end of the probe 213 and the reference connector 112. In some embodiments, the testing module can be a Vector Network Analyzer (VNA). The second end of the probe 213 can be connected to the first VNA port via an RF cable. The reference connector 112 can be connected to the second VNA port via an RF cable. During the measurement of the electrical characteristic, the VNA transmits a signal to the probe 213 through the first VNA port. The signal then passes through the test path and is received by the reference connector 112 with a certain magnitude. The electrical characteristic can be calculated based on the input signal transmitted to the probe 213 and the output signal received by the reference connector 112. It can be appreciated that the VNA can also transmit a signal to the reference connector 112 through the second VNA port. The signal then passes through the test path and is received by the probe 213 with a certain magnitude. The electrical characteristic can be calculated based on the input signal transmitted to the reference connector 112 and the output signal received by the probe 213.

In some embodiments, the electrical characteristic can be the path loss between the probe 213 and the reference connector 112. More specifically, the path loss can be, e.g., the impedance of the test path between the probe 213 and the reference connector 112, which is measured by the testing module.

In the present application, each conductive contact pad is aligned with and connected to one of the plurality of contact pins of the socket unit when the testing device is connected to the socket unit of the electronic device by providing a probe guiding block in the probe assembly of the testing device that mates with the testing cavity of the socket unit of the electronic device and a plurality of conductive contact pads in the substrate. The testing device can be conveniently and reliably connected to the socket unit of the electronic device by this structural design, thus improving the accuracy of the test results. Furthermore, when using the electronic device to test an electronic component, calibrating the measurement results of electronic components using the test result of the electronic device 100 can improve the accuracy of the final measurement results of electronic components.

FIG. 1F is a cutaway view of a testing device according to an embodiment of the present application. As shown in FIG. 1F, the testing device 200 includes a fastener 230, a spacer 240 and a locking assembly 250. The housing includes a guiding block cavity 221, a probe hole 222 and a lateral fastener hole 223 horizontally extending through a side wall of the housing 220. The guiding block cavity 221 is used to jointly accommodate the probe guiding block 211 with the testing cavity. The probe hole 222 extends vertically through the housing 220 and is connected to the probe passage 214 to allow the probe to extend through the probe hole 222 and the probe passage 214. The probe guiding block 211 further includes a lateral fastener groove (not shown) formed at a side wall of the probe guiding block 211, and the lateral fastener groove is connected to the lateral fastener hole 223. In some embodiments, the fastener 230 can be a screw. The fastener 230 extends through the lateral fastener hole 223 and is embedded in the lateral fastener groove. It can be understood that the fastener 230 can achieve a reliable connection between the housing 220 and the probe guiding block 211, thereby achieving a reliable connection between the housing 220 and the probe assembly 210 as a whole. In some embodiments, by changing a length of the fastener 230 embedded in the lateral fastener groove, a fastening force of the probe guiding block 211 relative to the housing 220 can be changed, thereby changing a vertical depth of the probe guiding block 211 relative to the guiding block cavity 221.

As shown in the enlarged view of the dashed box in FIG. 1F, the spacer 240 is disposed between the housing 220 and the probe guiding block 211 for adjusting the distance between the housing 220 and the probe guiding block 211. In some embodiments, the spacer 240 can be a gasket, and the distance between the housing 220 and the probe guiding block 211 is adjusted by selecting gaskets of different thicknesses. In some embodiments, the gasket can be an elastic gasket. When the length of the fastener 230 embedded in the lateral fastener groove is changed, the fastening force of the probe guiding block 211 relative to the housing 220 can be changed, thereby changing the force applied to the elastic gasket. As a result, the elastic gasket can be compressed or relaxed, which in turn changes the vertical depth of the probe guiding block 211 relative to the guiding block receiving cavity 221.

In some embodiments, the locking assembly 250 is disposed on an outer surface of the side wall of the housing 220 and includes a locking body 251 and a pivot connector 252. The locking body 251 has an overall elongated shape, and includes a handle portion 253 formed at a first end of the locking body 251 and a locking portion 254 formed at the second end of the locking body 251. The pivot connector 252 extends through the locking body 251 and rotatably connects the locking body 251 to the outer surface of the side wall of the housing 220. Specifically, the pivot connector 252 can be cylindrical and extend through the middle section of the locking body 251. When the handle portion 253 is applied with an external pressing force, the locking body 251 rotates about the pivot connector 252, so that the locking portion 254 moves away from the outer surface of the side wall of the housing. That is, the locking portion 254 is in an open state. When the force applied to the handle portion 253 is removed, the locking portion 254 moves closer to the outer surface of the side wall of the housing. That is, the locking portion 254 is in a locked state. In some embodiments, the locking portion 254 can also include an engaging groove for engaging and fixing the housing 220 to the socket body 121. With this locking assembly, the testing device 200 can be easily removed from or connected to the electronic device 100. In addition, when the testing device 200 is connected to the electronic device 100, this locking assembly can fix the testing device 200 with the electronic device 100, preventing displacement therebetween during testing which may result in signal disconnection. In this way, the accuracy of testing is further improved.

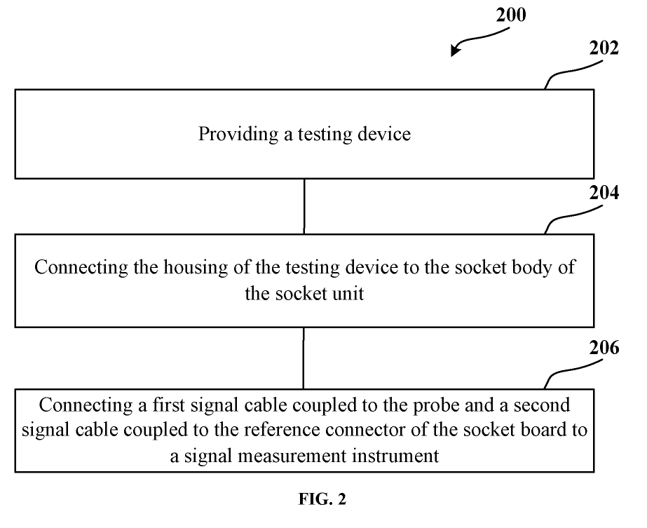

FIG. 2 illustrates a method for testing an electronic device according to an embodiment of the present application.

In this embodiment, the electronic device includes a socket board, a plurality of contact pads on the socket board, and a socket unit mounted on the socket board. The socket unit includes a socket body, a testing cavity in the socket body and a plurality of contact pins vertically extending through the socket body and exposed from the testing cavity. Each contact pin is aligned with and operably connected to one of the plurality of contact pads.

As shown in FIG. 2, in step S202, a testing device is provided. The testing device includes a probe assembly and a housing coupled to the probe assembly. The probe assembly includes: a probe guiding block matable with the testing cavity to be operably accommodated in the testing cavity. The probe guiding block includes a probe passage vertically extending through the probe guiding block. The probe assembly further includes a substrate disposed at a bottom of the probe guiding block, and the substrate includes a plurality of conductive contact pads formed at a first side of the substrate and a probe connector mounted on a second side of the substrate, the first side being opposite to the second side. The probe connector is electrically coupled to the plurality of conductive contact pads. The probe assembly further includes a probe extending through and accommodated in the probe passage, and the probe includes a first end connected to the probe connector and a second end facing away from the probe connector.

As shown in FIG. 2, in step S204, the housing of the testing device is connected to the socket body of the socket unit such that the probe guiding block is accommodated in the testing cavity and each conductive contact pad of the plurality of conductive contact pads is aligned with and connected to one of the plurality of contact pins, thereby electrically leading out the plurality of contact pins from the electronic device.

As shown in FIG. 2, in step S206, a first signal cable coupled to the probe and a second signal cable coupled to the reference connector of the socket board are connected to a signal measurement instrument, to enable testing of the electronic device by the signal measurement instrument through the testing device.

In this embodiment, the structure of the electronic device and the testing device can refer to the above device embodiment of the present application, which will not be repeated here. In this embodiment, the order of steps S204, and S206 can be interchanged.

The testing device provided in the test method of this embodiment includes a probe guiding block in the probe assembly that mates with the testing cavity of the socket unit of the electronic device and a plurality of conductive contact pads in the substrate. Each conductive contact pad is aligned with and connected to one of the plurality of contact pins of the socket unit when the testing device is connected to the socket unit of the electronic device. The testing device can be conveniently and reliably connected to the socket unit of the electronic device by this structural design, thus improving the accuracy of the test result.

In some embodiments, the housing of the testing device further includes a lateral fastener hole horizontally extending through a side wall of the housing. The probe guiding block includes a lateral fastener groove formed at a side wall of the probe guiding block, and the lateral fastener groove is connected to the lateral fastener hole. The testing device further includes a fastener extending through the lateral fastener hole and embedded in the lateral fastener groove.

In some embodiments, the testing device further includes a locking assembly mounted on an outer surface of side wall of the housing. The structure of the locking assembly can refer to the description of the above embodiment of the testing device. Step S204 further includes: pressing a handle portion at a first end of a locking body to drive a locking portion at a second end of the locking body to rotate about a pivot connector of the locking assembly such that the locking portion moves away from the outer surface of the side wall of the housing; mounting operably the housing of the testing device on the socket body of the socket unit; and releasing the handle portion to lock a relative position of the housing of the testing device and the socket body of the socket unit. With this locking assembly, the testing device can be easily removed from or connected to the electronic device. In addition, when the testing device is connected to the electronic device, this locking assembly can fix the testing device with the electronic device, preventing displacement thereof during testing, which may result in undesired signal disconnection. In this way, the accuracy of testing can be further improved.

While the exemplary various parts of testing device and method for testing an electronic device of the present application is described in conjunction with corresponding figures. For the purpose of clarity, these drawings do not show all aspects of each illustrated component. Any illustrated components and/or methods provided herein may share any or all features with any or all other components and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A testing device for testing an electronic device, wherein the electronic device comprises a socket board, a plurality of contact pads on the socket board, and a socket unit mounted on the socket board; wherein the socket unit comprises a socket body, a testing cavity in the socket body and a plurality of contact pins vertically extending through the socket body and exposed from the testing cavity, each contact pin being aligned with and operably connected to one of the plurality of contact pads; wherein the testing device is operably connected to the electronic device, and comprises:
a probe assembly configured to operably contact the plurality of contact pins to electrically lead out the plurality of contact pins from the electronic device, and comprising:
a probe guiding block matable with the testing cavity to be operably accommodated in the testing cavity, wherein the probe guiding block comprises a probe passage vertically extending through the probe guiding block;
a substrate disposed at a bottom of the probe guiding block, wherein the substrate comprises a plurality of conductive contact pads formed at a first side of the substrate and a probe connector mounted at a second side of the substrate, the first side being opposite to the second side, the probe connector being electrically coupled to the plurality of conductive contact pads, wherein the substrate is configured that each conductive contact pad of the plurality of conductive contact pads is aligned with and connected to one of the plurality of contact pins when the probe guiding block is accommodated in the testing cavity; and
a probe extending through and accommodated in the probe passage, wherein the probe comprises a first end connected to the probe connector and a second end facing away from the probe connector; and
a housing coupled to the probe assembly, and configured to operably fix the probe assembly to the socket body of the electronic device to allow the probe to be electrically coupled to the socket board of the electronic device through the substrate.

2. The testing device according to claim 1, wherein the housing comprises:
a guiding block cavity configured to jointly accommodate the probe guiding block with the testing cavity; and
a probe hole extending vertically through the housing and connected to the probe passage to allow the probe to extend through and be accommodated in the probe hole.

3. The testing device according to claim 1, wherein the housing comprises a lateral fastener hole horizontally extending through a side wall of the housing, the probe guiding block comprises a lateral fastener groove formed at a side wall of the probe guiding block and the lateral fastener groove is connected to the lateral fastener hole; wherein the testing device further comprises:
a fastener extending through the lateral fastener hole and embedded in the lateral fastener groove.

4. The testing device according to claim 3, wherein the fastener is further configured to change a vertical depth of the probe guiding block relative to the guiding block cavity by changing a length of the fastener embedded in the lateral fastener groove.

5. The testing device according to claim 1, wherein the testing device further comprises:
a spacer disposed between the housing and the probe guiding block, and configured to adjust a distance between the housing and the probe guiding block.

6. The testing device according to claim 1, wherein the testing device further comprises:
a locking assembly disposed on an outer side wall of the housing, and configured to lock a position of the testing device relative to the electronic device when the testing device is connected to the electronic device, wherein the locking member comprises:
a locking body comprising a handle portion disposed at a first end of the locking body and a locking portion disposed at a second end of the locking body, wherein the handle portion is configured to receive an external pressing force; and
a pivot connector extending through the locking body and configured to rotatably connect the locking body to the outer side wall of the housing.

7. The testing device according to claim 1, wherein the plurality of contact pins comprise pogo pins.

8. The testing device according to claim 1, wherein the electronic device further comprises a reference connector mounted on the socket board and a signaling trace extending between the signal contact pad and the reference connector which are electrically coupled with each other; and wherein the testing device further comprises:
a testing module configured to generate a test result by measuring an electrical characteristic associated with a test path between the reference connector and the probe which are electrically coupled with each other by the plurality of contact pins when the testing device is connected to the socket unit.

9. A testing method for testing an electronic device, wherein the electronic device comprises a socket board, a plurality of contact pads on the socket board, and a socket unit mounted on the socket board; wherein the socket unit comprises a socket body, a testing cavity in the socket body and a plurality of contact pins vertically extending through the socket body and exposed from the testing cavity, each contact pin being aligned with and operably connected to one of the plurality of contact pads; and wherein the method comprises:
providing a testing device, wherein the testing device comprises:
a probe assembly configured to operably contact the plurality of contact pins to electrically lead out the plurality of contact pins from the electronic device, and comprising:
a probe guiding block matable with the testing cavity to be operably accommodated in the testing cavity, wherein the probe guiding block comprises a probe passage vertically extending through the probe guiding block;
a substrate disposed at a bottom of the probe guiding block, wherein the substrate comprises a plurality of conductive contact pads formed at a first side of the substrate and a probe connector mounted at a second side of the substrate, the first side being opposite to the second side, the probe connector being electrically coupled to the plurality of conductive contact pads; and
a probe extending through and accommodated in the probe passage, wherein the probe comprises a first end connected to the probe connector and a second end facing away from the probe connector; and
a housing coupled to the probe assembly;
connecting the housing of the testing device to the socket body of the socket unit, such that the probe guiding block is accommodated in the testing cavity and each conductive contact pad of the plurality of conductive contact pads is aligned with and connected to one of the plurality of contact pins; and
connecting a first signal cable coupled to the probe and a second signal cable coupled to the reference connector of the socket board to a signal measurement instrument, to enable testing of the electronic device by the signal measurement instrument through the testing device.

10. The method according to claim 9, wherein the housing comprises a lateral fastener hole horizontally extending through a side wall of the housing, the probe guiding block comprises a lateral fastener groove formed at a side wall of the probe guiding block and the lateral fastener groove is connected to the lateral fastener hole; wherein the testing device further comprises a fastener extending through the lateral fastener hole and embedded in the lateral fastener groove.

11. The method according to claim 9, wherein the testing device further comprises a locking assembly disposed on an outer surface of a side wall of the housing; and wherein connecting the housing of the testing device to the socket body of the socket unit comprises:
pressing a handle portion at a first end of a locking body to drive a locking portion at a second end of the locking body to rotate about a pivot connector of the locking assembly such that the locking portion moves away from the outer surface of the side wall of the housing;
mounting operably the housing of the testing device on the socket body of the socket unit; and
releasing the handle portion to lock a position of the housing of the testing device relative to the socket body of the socket unit.
